(19) United States
(12) Patent Application Publication
(10) Pub. No.: US 2006/0078678 A1
(43) Pub. Date: Apr. 13, 2006

(54) Method of forming a thin film by atomic layer deposition

(75) Inventors: Seok-Jun Won, Seoul (KR); Yong-Kuk Jeong, Seoul (KR); Dae-Jin Kwon, Seoul (KR); Min-Woo Song, Seongnam-si (KR); Weon-Hong Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/247,295

(22) Filed: Oct. 11, 2005

(30) Foreign Application Priority Data
Oct. 13, 2004 (KR) 10-2004-0081940

(51) Int. Cl. C23C 16/00

(52) U.S. Cl. 427/248.1

(57) ABSTRACT

Methods of forming a thin film by atomic layer deposition are disclosed. These methods generally include the steps of loading a substrate into a reaction chamber, and injecting a first source gas containing a first atom into the reaction chamber to form a chemical adsorption layer containing the first atom on the substrate. In one representative embodiment, a first reaction gas is then injected into the reaction chamber while a first plasma power is applied to the reaction chamber such that the first reaction gas reacts with the chemical adsorption layer containing the first atom to form a first thin film on the substrate. A second source gas containing a second atom is then injected into the reaction chamber to form a chemical adsorption layer containing the second atom on the substrate having the first thin film. A second reaction gas is next injected into the reaction chamber while a second plasma power, which is higher than the first plasma power, is applied to the reaction chamber such that the second reaction gas reacts with the chemical adsorption layer containing the second atom to form a second thin film on the substrate. The first plasma power may be a value selected in a range equal to or greater than 0 W and less than about 500 W, and the second plasma power may be a value selected in a range greater than the first plasma power and less than about 2000 W. A thickness of the second thin film may be equal to or greater than a thickness of the first thin film.

### CROSS-REFERENCE TO RELATED APPLICATION

This application claims the benefit of Korean Patent Application No. 2004-81940, filed Oct. 13, 2004, the contents of which are hereby incorporated herein by reference in their entirety.

### BACKGROUND OF THE INVENTION

1. Field of the Invention

The present invention relates to a method of forming a thin film, and more particularly, to a method of forming a thin film by atomic layer deposition (ALD).

2. Description of the Related Art

Techniques for controlling the thickness and uniformity of thin films deposited on a suitable substrate and used for semiconductor devices and display devices have become increasingly important in fabrication processes.

Physical vapor deposition (PVD) methods and chemical vapor deposition (CVD) methods are well known and widely employed for forming thin films. Also, atomic layer deposition (ALD) methods have found increasing use in recent years. As is well known in the art, the PVD method has a disadvantage in that step coverage for smoothly burying a surface is poor when the step occurs on the surface of the substrate. In addition, the CVD method is limited in thin film formation by temperature considerations and by the difficulties of accurately controlling the thickness of CVD thin films in the range of several Angstrom units (Å).

Accordingly, the ALD method is being used to try to overcome the limits of the PVD and CVD methods and to form thin films with controlled thicknesses on the order of an atomic layer unit. According to the ALD method, source gases for forming a particular thin film are not simultaneously supplied to a substrate surface but rather are separately supplied as pulses in a sequenced, time-division manner. In supplying the required sequence of gases, valves disposed in respective gas pipes are opened and closed at different times from each other so that the gases are not mixed but instead are sequentially supplied into a reaction chamber containing the substrate at different times from each other. When active or reactant gases are supplied at a predetermined flow rate in a sequential, time division manner, it is typical to also supply a purge gas between the steps of supplying the respective reactant gases to remove remaining reactant and/or byproduct gases from the reaction chamber. The ALD method has several advantages, including providing good step coverage and forming a thin film having a substantially uniform thickness on a large-surface area substrate. By repeating the ALD thin film formation steps a controlled number of times, the process may be controlled to accurately adjust the thickness of the thin film. On the other hand, the ALD method has a disadvantage in that because the deposition cycle of an atomic layer unit must typically be repeated multiple times to form the desired thin film, the total process (fabrication) time is thereby increased.

In recent years, in order to improve the deposition speed when using the ALD method, a plasma enhanced atomic layer deposition (PEALD) method using plasma has been proposed. According to the PEALD method, a first reaction gas is supplied to be adsorbed on the surface of the substrate, a purge gas is then supplied to remove the first reaction gas remaining in a reaction chamber, and thereafter a second reaction gas is supplied into the reaction chamber under a process condition of applying plasma power to the reaction chamber. The PEALD method has advantages over conventional ALD techniques in that a deposition speed may be improved to decrease the process time while still maintaining the advantages associated with the ALD method. Moreover, the reactivity of the reaction gas may be increased using the PEALD method in order to broaden the useable process temperature range. However, when high power is used for the process condition of applying plasma power, the substrate surface may be damaged due to the plasma, and the uniformity of the deposited thin film may also be degraded.

A method of forming a thin film using the PEALD method is disclosed in U.S. Pat. No. 6,730,614 B1 entitled “Method of Forming a Thin Film in a Semiconductor Device”, which patent is incorporated herein by reference.

FIG. 1 is a recipe diagram showing the steps in a single deposition cycle for explaining a method of forming a thin film in a semiconductor device according to U.S. Pat. No. 6,730,614 B1.

Referring to FIG. 1, the method of forming the thin film in the semiconductor device as disclosed in U.S. Pat. No. 6,730,614 B1 forms the thin film by alternately performing the ALD method and the PEALD method.

To detail this process, the ALD method taught by U.S. Pat. No. 6,730,614 includes the following steps as one cycle (which is repeatedly performed to form a thin film of a desired thickness): a step (A) of supplying precursor(s) into a deposition chamber under conditions so as to adsorb the precursor(s) on the surface of the substrate; a cleaning step (B) of removing the remaining precursor(s) which is/are not adsorbed on the substrate within the deposition chamber; a step (C) of supplying a first reaction gas to the chamber under such conditions that the gas reacts with the precursor(s) to form an atomic layer thin film on the substrate surface; and a cleaning step (D) of removing the first reaction gas that does not react with the precursor(s) and reaction by-products. In addition, a PEALD operation is carried out which includes the following steps as one cycle (which is repeatedly performed): a step (A′) of supplying precursor(s) into a deposition chamber under conditions so as to adsorb the precursor(s) on the surface of a substrate; a cleaning step (B′) of removing the remaining precursor(s) which is/are not adsorbed on the substrate within the deposition chamber; a step (C′) of supplying a second reaction gas while generating plasma under such conditions that the gas reacts with the precursor(s) to form an atomic layer thin film on the substrate surface; and a cleaning step (D′) of removing the second reaction gas that does not react with the precursor(s) and reaction by-products.

However, in carrying out this technique, the surface of the substrate may be damaged due to the plasma when the plasma is generated per one cycle.

As a result, a technique is required which is capable of avoiding, preventing or minimizing damage to the surface of the substrate due to the plasma and also of improving the uniformity of the deposited thin film.

### SUMMARY OF THE INVENTION

Embodiments of the present invention provide methods of forming a thin film having a good uniformity and an improved deposition speed.

In one aspect, the present invention is generally directed to methods of forming a thin film by atomic layer deposition. The methods include steps of loading a substrate into a reaction chamber and injecting a first source gas containing a first atom into the reaction chamber to form a chemical adsorption layer containing the first atom on the substrate. A first reaction gas is then injected into the reaction chamber while a first plasma power is applied to the reaction chamber such that the first reaction gas reacts with the previously-formed chemical adsorption layer containing the first atom to form a first thin film on the substrate. A second source gas containing a second atom is thereafter injected into the reaction chamber to form a chemical adsorption layer containing the second atom on the substrate having the first thin film. A second reaction gas is then injected into the reaction chamber while a second plasma power, which is higher than the first plasma power, is applied to the reaction chamber such that the second reaction gas reacts with the chemical adsorption layer containing the second atom to form a second thin film on the substrate.

The first plasma power may be a value selected in a power range equal to or greater than 0 W (zero watts) and less than 500 W (500 watts). The second plasma power may be a value selected in a power range greater than the first plasma power and less than 2000 W (2000 watts).

The first atom may be at least one member selected from the group consisting of aluminum (Al), hafnium (Hf), zirconium (Zr), lanthanum (La), silicon (Si), tantalum (Ta), titanium (Ti), strontium (Sr), barium (Ba), lead (Pb), chromium (Cr), molybdenum (Mo), tungsten (W), yttrium (Y), and manganese (Mn).

The first reaction gas may contain at least one member selected from an oxygen (O)-containing gas, a nitrogen (N)-containing gas and a hydrogen(H₂) gas, wherein the oxygen (O)-containing gas may be at least one member selected from the group consisting of O₂, O₃, H₂O, H₂O₂, NO₂, and N₂O, and wherein the nitrogen (N)-containing gas may be at least one member selected from the group consisting of N₂, NH₃, NO₂, and N₂O.

The second atom may be at least one member selected from the group consisting of Al, Hf, Zr, La, Si, Ta, Ti, Sr, Ba, Pb, Cr, Mo, W, Y, and Mn.

The second reaction gas may contain at least one member selected from an oxygen (O)-containing gas, a nitrogen (N)-containing gas and a hydrogen(H₂) gas, wherein the oxygen (O)-containing gas may be at least one member selected from the group consisting of O₂, O₃, NO₂, and N₂O, and the nitrogen (N)-containing gas may be at least one member selected from the group consisting of N₂, NH₃, NO₂, and N₂O.

The first thin film may be one of an oxide layer, a nitride layer or an oxynitride layer of the first atom, and the second thin film may be one of an oxide layer, a nitride layer or an oxynitride layer of the second atom. In addition, a thickness of the second thin film may be equal to or larger than a thickness of the first thin film. The second thin film may be formed of the same material as the first thin film; or, alternatively, it may also be formed of a material different from that of the first thin film.

In accordance with some embodiments of the present invention, the method includes a step of injecting a first reaction gas into the reaction chamber while applying a first plasma power to the reaction chamber when the first thin film is formed; and, the method also includes a step of injecting a second reaction gas into the reaction chamber while applying a second plasma power, which is higher than the first plasma power applied to the reaction chamber, when the second thin film is formed. Accordingly, the substrate having the first thin film formed thereon may be protected against surface damage due to the plasma even when a high plasma power is used as the second plasma power. In addition, the first thin film is formed using a plasma power lower than the second plasma power so that the first thin film is formed having a good uniformity. The first thin film and the second thin film may be stacked to act as a composite thin film. In this case, the steps of forming the first thin film may be repeatedly carried out two or more times to adjust the properties and deposition speed of the completed composite thin film; also, the steps of forming the second thin film may also be repeatedly carried out two or more times to adjust the properties and deposition speed of the completed composite thin film. In addition, the steps of forming the first thin film and the steps of forming the second thin film may be repeatedly carried out to adjust the properties and deposition speed of the composite thin film.

In accordance with another aspect, the present invention is directed to a variation of previously-described methods of forming a thin film by atomic layer deposition. Such variation method includes the steps of loading a substrate into a reaction chamber and injecting a first source gas containing a first atom into the reaction chamber to form a chemical adsorption layer containing the first atom on a substrate surface. A first reaction gas is then injected into the reaction chamber under a process condition hereinafter referred to as a first plasma-on-time condition such that the first reaction gas reacts with the chemical adsorption layer containing the first atom to form a first thin film on the substrate surface. A second source gas containing a second atom is then injected into the reaction chamber to form a chemical adsorption layer containing the second atom on the substrate surface having the first thin film formed thereon. A second reaction gas is then injected into the reaction chamber under a process condition hereinafter referred to as a second plasma-on-time condition, which is for a longer period of time than the first plasma-on-time condition, such that the second reaction gas reacts with the chemical adsorption layer containing the second atom to form a second thin film on the substrate surface.

The first plasma-on-time condition may be established for a time period selected in a range equal to or, preferably, greater than 0 second and less than about 1 second, and the second plasma-on-time condition may be established for a time period selected in a range greater than the time period used for the first plasma-on-time condition and less than about 30 seconds. The art in this technical field suggests that the uniformity of the deposited thin film may be degraded as plasma treatment time is lengthened. On the contrary, it has been found in accordance with this invention that, as the plasma-on-time condition is lengthened within suitable limits, a thin film having a good leakage current characteristic may be obtained. Accordingly, and somewhat surprisingly, a thin film having a good leakage current characteristic and a good uniformity may be obtained by the methods of this invention.

In accordance with still another aspect, the present invention is directed to another variation of previously-described methods of forming a thin film by atomic layer deposition. Such variation method includes the steps of loading a substrate into a reaction chamber and injecting a first source gas containing a first atom into the reaction chamber to form a chemical adsorption layer containing the first atom on a substrate surface. A first reaction gas is then injected into the reaction chamber at a first flow rate such that the first reaction gas reacts with the chemical adsorption layer containing the first atom to form a first thin film on the substrate surface. A second source gas containing a second atom is then injected into the reaction chamber to form a chemical adsorption layer containing the second atom on the substrate surface having the first thin film. A second reaction gas is then injected into the reaction chamber at a second flow rate that is higher than the first flow rate such that the second reaction gas reacts with the chemical adsorption layer containing the second atom to form a second thin film on the substrate surface.

In this invention embodiment, the first flow rate may be a value selected in a range greater than 0 sccm (standard cubic centimeter per minute) and less than about 300 sccm, and the second flow rate may be a value selected in a range greater than the first flow rate and less than about 5000 sccm.

In accordance with yet another aspect, the present invention is directed to yet another variation of previously-described methods of forming a thin film by atomic layer deposition. Such variation method includes the steps of loading a substrate into a reaction chamber and injecting a first source gas containing a first atom into the reaction chamber to form a chemical adsorption layer containing the first atom on a substrate surface. A first reaction gas is then injected into the reaction chamber under a process condition comprising a first pressure such that the first reaction gas reacts with the chemical adsorption layer containing the first atom to form a first thin film on the substrate surface. A second source gas containing a second atom is then injected into the reaction chamber to form a chemical adsorption layer containing the second atom on the substrate surface having the first thin film. A second reaction gas is then injected into the reaction chamber under a process condition comprising a second pressure that is lower than the first pressure such that the second reaction gas reacts with the chemical adsorption layer containing the second atom to form a second thin film on the substrate surface.

In this invention embodiment, the first pressure may be a value selected in a range equal to or greater than about 3 Torr and less than about 30 Torr, and the second pressure is a value selected in a range greater than 0 Torr and less than the first pressure.

In accordance with yet another aspect, the present invention is directed to yet another variation of previously-described methods of forming a thin film by atomic layer deposition. Such variation method includes the steps of loading a substrate into a reaction chamber and injecting a first source gas containing a first atom into the reaction chamber to form a chemical adsorption layer containing the first atom on a substrate surface. A first reaction gas is then injected into the reaction chamber at a first flow rate and also under a process condition comprising a first pressure such that the first reaction gas reacts with the chemical adsorption layer containing the first atom to form a first thin film on the substrate surface. A second source gas containing a second atom is then injected into the reaction chamber to form a chemical adsorption layer containing the second atom on the substrate surface having the first thin film. A second reaction gas is then injected into the reaction chamber at a second flow rate that is higher than the first flow rate, and also under a process condition comprising a second pressure that is lower than the first pressure, such that the second reaction gas reacts with the chemical adsorption layer containing the second atom to form a second thin film on the substrate surface.

In this invention embodiment, the first flow rate may be a value selected in a range greater than 0 sccm (standard cubic centimeter per minute) and less than about 300 sccm, the second flow rate may be a value selected in a range greater than the first flow rate and less than about 5000 sccm, the first pressure may be a value selected in a range equal to or greater than about 3 Torr and less than about 30 Torr, and the second pressure may be a value selected in a range greater than 0 Torr and less than the first pressure.

In accordance with yet another aspect, the present invention is directed to still another variation of previously-described methods of forming a thin film by atomic layer deposition. Such variation method includes the steps of loading a substrate into a reaction chamber and injecting a first source gas containing a first atom into the reaction chamber to form a chemical adsorption layer containing the first atom on a substrate surface. A first reaction gas having a first chemical reactivity value is then injected into the reaction chamber such that the first reaction gas reacts with the chemical adsorption layer containing the first atom to form a first thin film on the substrate surface. A second source gas containing a second atom is then injected into the reaction chamber to form a chemical adsorption layer containing the second atom on the substrate surface having the first thin film. A second reaction gas having a second chemical reactivity value that is higher than the first chemical reactivity value is then injected into the reaction chamber such that the second reaction gas reacts with the chemical adsorption layer containing the second atom to form a second thin film on the substrate surface.

In this invention embodiment, the first reaction gas having the first chemical reactivity value may be a gas having a relatively low chemical reactivity relative to the first atom, and the second reaction gas having the second chemical reactivity value may be a gas having a relatively high chemical reactivity relative to the second atom.

### BRIEF DESCRIPTION OF THE DRAWINGS

The foregoing and other objects, features and advantages of the present invention will be apparent from the more particular description of preferred embodiments of the invention, as illustrated in the accompanying drawings. The drawings are not necessarily to scale, emphasis instead being placed upon illustrating the principles of the invention.

FIG. 1 is a recipe diagram for explaining a series of sequential process steps in a method of forming a thin film in accordance with prior art in this field.

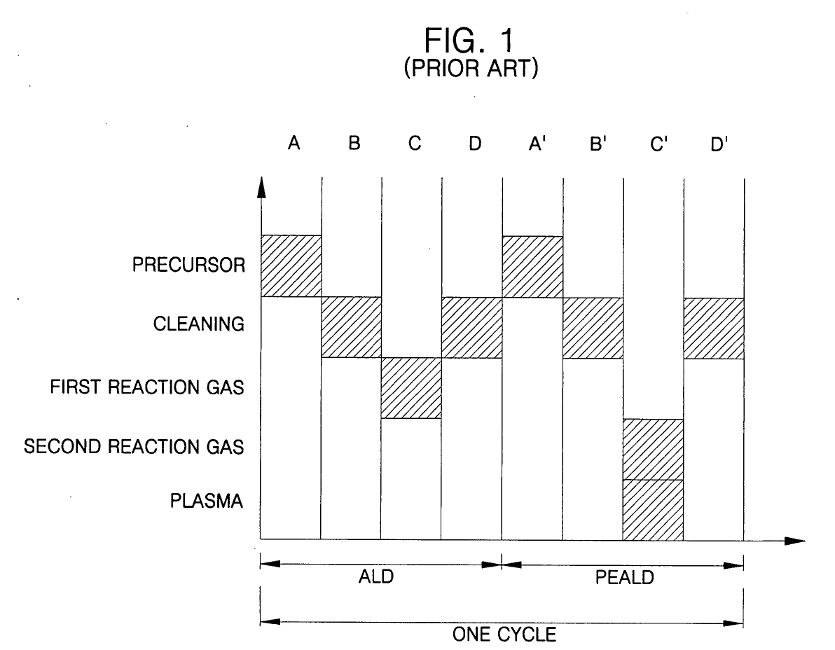

FIG. 2 is a process flow chart illustrating process steps in a method of forming a thin film by an ALD method in accordance with the present invention.

FIG. 3 is a scatter diagram illustrating uniformity of thin films prepared in accordance with examples of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these illustrated and more fully described embodiments are provided so that this disclosure will be thorough and complete, and will fully convey the scope of the invention to those skilled in the art. In the drawings, the thicknesses of layers and regions are exaggerated for clarity. Like numbers refer to like elements or process steps throughout the specification.

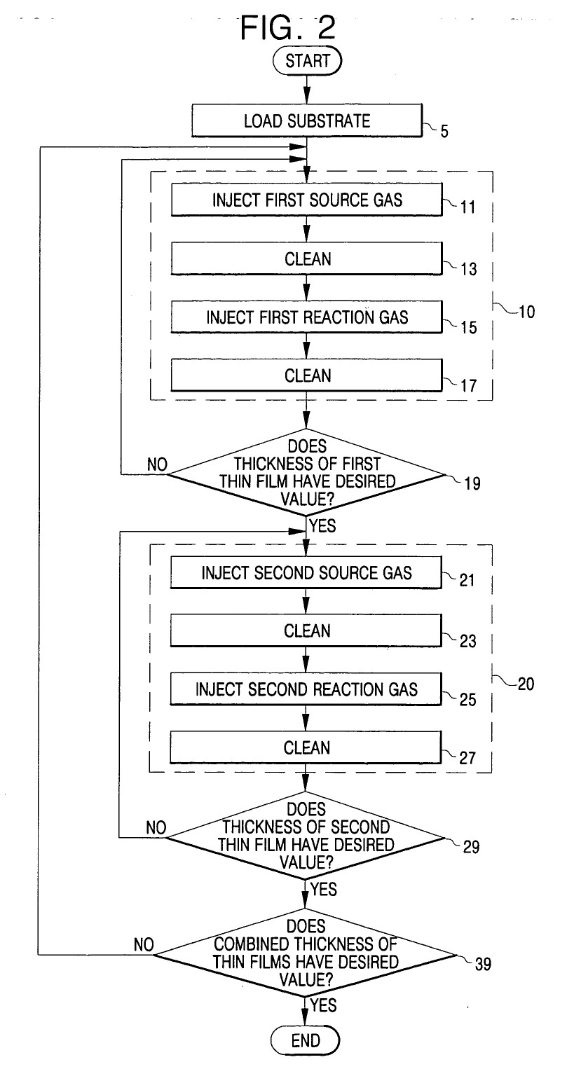

FIG. 2 is a process flow chart illustrating process steps in a method of forming a thin film by an ALD method in accordance with the present invention.

Referring to FIG. 2, the illustrated method of forming a thin film in accordance with embodiments of the present invention includes a preliminary step of loading a substrate into a reaction chamber of an atomic layer deposition apparatus (reference numeral 5 in FIG. 2).

The reaction chamber may be a single type or a batch type reaction vessel. The substrate may be a semiconductor substrate such as a silicon substrate, and an isolation layer may be formed on the substrate by known techniques prior to starting the thin film formation steps of this invention. In addition, a three-dimensional structure, such as a bottom electrode of a cylindrical capacitor, may also or alternatively be formed on the substrate by known techniques.

A cycle of forming a first thin film (10) (represented by the sequence of process steps identified by reference numerals 11 to 17 in FIG. 2) is repeatedly performed to form the first thin film having a desired thickness on a surface of the substrate. The cycle of forming the first thin film (10) may include a step of injecting a first source gas (reference numeral 11 in FIG. 2), a step of discharging the first source gas remaining within the reaction chamber to clean the inside of the reaction chamber (reference numeral 13 in FIG. 2), a step of applying a first plasma power to the reaction chamber while injecting a first reaction gas (reference numeral 15 in FIG. 2), and a step of cleaning the inside of the reaction chamber (reference numeral 17 in FIG. 2).

Describing this method in greater detail, the first source gas containing a first atom is injected into the reaction chamber where the substrate is already loaded (reference numeral 11 in FIG. 2). The first atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the first atom is formed on an exposed surface of the substrate. After the chemical adsorption layer containing the first atom is formed, the first source gas remaining within the reaction chamber is discharged to clean the inside of the reaction chamber (reference numeral 13 in FIG. 2). A purge gas may be injected into the reaction chamber in order to assist in the discharge of the first source gas. An inactive or substantially inert gas such as argon (Ar), helium (He), or nitrogen (N₂) may typically be employed as the purge gas. Subsequently, a first plasma power is applied to the reaction chamber while the first reaction gas is injected (reference numeral 15 in FIG. 2). The first plasma power may have a value selected in the range equal to or greater than 0 W and less than about 500 W. The first reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the first reaction gas react with each other to form the first thin film on the substrate surface. The first thin film may be an oxide layer, a nitride layer or an oxynitride layer of the first atom. Subsequently, any first reaction gas remaining within the reaction chamber, and any by-product generated due to the reaction between the chemical adsorption layer and the first reaction gas, are discharged to clean the inside of the reaction chamber (reference numeral 17 in FIG. 2). A purge gas may be injected into the reaction chamber in order to assist in the discharge of the first reaction gas and the by-product. An inactive or substantially inert gas such as argon (Ar), helium (He), or nitrogen (N₂) may typically be employed as the purge gas. It is then determined whether the first thin film having a desired thickness has been formed (reference numeral 19 in FIG. 2). The cycle of forming the first thin film (10) is repeatedly performed until the first thin film having the desired thickness has been formed on the substrate.

A cycle of forming a second thin film (20) (represented by the sequence of process steps identified by reference numerals 21 to 27 in FIG. 2) is repeatedly performed on the substrate having the first thin film to form the second thin film having a desired thickness. The cycle of forming the second thin film (20) may include a step of injecting a second source gas (reference numeral 21 in FIG. 2), a step of discharging the second source gas remaining within the reaction chamber to clean the inside of the reaction chamber (reference numeral 23 in FIG. 2), a step of injecting a second reaction gas while applying a second plasma power that is higher than the first plasma power to the reaction chamber (reference numeral 25 in FIG. 2), and a step of cleaning the inside of the reaction chamber (reference numeral 27 in FIG. 2).

Describing this method in greater detail, the second source gas containing a second atom is injected into the reaction chamber (reference numeral 21 in FIG. 2). The second atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the second atom is formed on the substrate surface having the first thin film. After the chemical adsorption layer containing the second atom is formed, the second source gas remaining within the reaction chamber is discharged to clean the inside of the reaction chamber (reference numeral 23 in FIG. 2). A purge gas may be injected into the reaction chamber in order to assist in the discharge of the second source gas. An inactive or substantially inert gas such as argon (Ar), helium (He), or nitrogen (N₂) may typically be employed as the purge gas. Subsequently, the second plasma power (which is higher than the first plasma power) is applied to the reaction chamber while the second reaction gas is injected (reference numeral 25 in FIG. 2). The second plasma power may have a value selected in the range greater than the first plasma power and less than about 2000 W. In accordance with this embodiment, the substrate having the first thin film will be protected from damage due to plasma even when the second plasma power is higher than the first plasma power used for forming the first thin film. The second reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, NO₂, and N₂O. The nitrogen (N)-containing gas may be at least one member selected from the group consisting of N₂, NH₃, NO₂, and N₂O. Under suitable conditions, the chemical adsorption layer and the second reaction gas react with each other to form the second thin film on the substrate surface. The second thin film may be an oxide layer, a nitride layer or an oxynitride layer of the second atom. Subsequently, any second reaction gas remaining within the reaction chamber, and any by-product generated due to the reaction between the chemical adsorption layer and the second reaction gas, are discharged to clean the inside of the reaction chamber (reference numeral 27 in FIG. 2). A purge gas may be injected into the reaction chamber in order to assist in the discharge of the second reaction gas and the by-product. An inactive or substantially inert gas such as argon (Ar), helium (He), or nitrogen (N₂) may typically be employed as the purge gas. It is then determined whether the second thin film has been formed to a desired thickness (reference numeral 29 in FIG. 2). The cycle of forming the second thin film (20) is repeatedly performed until the second thin film having the desired thickness has been formed on the substrate.

The first thin film and the second thin film are thereby formed as stacked films adapted to act as a composite thin film. It is then determined whether the composite thin film has a desired thickness (reference numeral 39 in FIG. 2). The cycle of forming the first thin film (10) and the cycle of forming the second thin film (20) may be repeatedly performed until a composite thin film having the desired thickness has been formed on the substrate.

According to the present embodiment as described above, the cycle of forming the first thin film (10) includes a step of injecting a first reaction gas while applying a first plasma power to the reaction chamber, and the cycle of forming the second thin film (20) includes a step of injecting a second reaction gas while applying a second plasma power that is higher than the first plasma power to the reaction chamber. As a result, the first thin film may be superior in uniformity as compared to the second thin film. In addition, deposition speed and the specific properties of the composite thin film may be adjusted by repeatedly performing the cycle of forming the first thin film (10) a desired number of times, and may also be adjusted by repeatedly performing the cycle of forming the second thin film (20) a desired number of times. In addition, the deposition speed and the specific properties of the composite thin film may be adjusted by repeatedly performing the two cycles of forming the first thin film (10) and the cycle of forming the second thin film (20) a desired number of times. Selecting an optimum number of repetitions of cycle (10), cycle (20), or combined cycles (10) and (20) in accordance with this invention to obtain a composite thin film having certain desirable properties would generally be a matter of routine experimentation. In a particularly desirable combination of properties which can be realized through the practice of this invention, surface damage to the substrate due to plasma may be prevented or minimized while a composite thin film having a good uniformity may be formed at a relatively fast deposition speed.

In different invention embodiments, the thickness of the second thin film may be equal to or larger than that of the first thin film.

The second thin film may be formed of the same material as the first thin film, or, alternatively, it may be formed of a material different from the first thin film.

Alternatively, another method of forming a thin film according to another embodiment of the present invention includes the step of loading a substrate into a reaction chamber of an atomic layer deposition apparatus (reference numeral 5 in FIG. 2).

A cycle of forming a first thin film (10) is repeatedly performed to form the first thin film having a desired thickness on a surface of the substrate. The cycle of forming the first thin film (10) may include a step of injecting a first source gas (reference numeral 11 in FIG. 2), a step of discharging the first source gas remaining within the reaction chamber to clean the inside of the reaction chamber (reference numeral 13 in FIG. 2), a step of injecting a first reaction gas into the reaction chamber under the process condition of a first plasma-on-time condition (reference numeral 15 in FIG. 2), and a step of cleaning the inside of the reaction chamber (reference numeral 17 in FIG. 2).

Describing this embodiment in greater detail, the first source gas containing a first atom is injected into the reaction chamber where the substrate is already loaded (reference numeral 11 in FIG. 2). The first atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the first atom is formed on an exposed surface of the substrate. After the chemical adsorption layer containing the first atom is formed, the first source gas remaining within the reaction chamber is discharged to clean the inside of the reaction chamber (reference numeral 13 in FIG. 2). Subsequently, the first reaction gas is injected into the reaction chamber under the process condition of the first plasma-on-time condition (reference numeral 15 in FIG. 2). The first plasma-on-time condition may have a value selected in the range equal to or greater than 0 second and less than about 1 second. The first reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the first reaction gas react with each other to form the first thin film on the substrate surface. The first thin film may be an oxide layer, a nitride layer or an oxynitride layer of the first atom. Subsequently, any first reaction gas remaining within the reaction chamber, and any by-product generated due to the reaction between the chemical adsorption layer and the first reaction gas, are discharged to clean the inside of the reaction chamber (reference numeral 17 in FIG. 2). It is then determined whether the first thin film has been formed to a desired thickness (reference numeral 19 in FIG. 2). The cycle of forming the first thin film (10) may be repeatedly performed until the first thin film having the desired thickness has been formed on the substrate.

A cycle of forming a second thin film (20) is repeatedly performed on the substrate having the first thin film to form the second thin film having a desired thickness. The cycle of forming the second thin film (20) may include a step of injecting a second source gas (reference numeral 21 in FIG. 2), a step of discharging the second source gas remaining within the reaction chamber to clean the inside of the reaction chamber (reference numeral 23 in FIG. 2), a step of injecting a second reaction gas under the process condition of a second plasma-on-time condition that is longer than the first plasma-on-time condition (reference numeral 25 in FIG. 2), and a step of cleaning the inside of the reaction chamber (reference numeral 27 in FIG. 2).

Describing this embodiment in greater detail, the second source gas containing a second atom is injected into the reaction chamber (reference numeral 21 in FIG. 2). The second atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the second atom is formed on the substrate surface having the first thin film. After the chemical adsorption layer containing the second atom is formed, the second source gas remaining within the reaction chamber is discharged to clean the inside of the reaction chamber (reference numeral 23 in FIG. 2). Subsequently, the second reaction gas is injected into the reaction chamber under the process condition of the second plasma-on-time condition, which is longer than the first plasma-on-time condition (reference numeral 25 in FIG. 2). The second plasma-on-time condition may be a value selected in the range greater than the duration of the first plasma-on-time condition and less than about 30 seconds. The second reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, NO₂, and N₂O. The nitrogen (N)-containing gas may be at least one member selected from the group consisting of N₂, NH₃, NO₂, and N₂O. Under suitable conditions, the chemical adsorption layer and the second reaction gas react with each other to form the second thin film on the substrate surface. The second thin film may be an oxide layer, a nitride layer or an oxynitride layer of the second atom. Subsequently, any second reaction gas remaining within the reaction chamber, and any by-product generated due to the reaction between the chemical adsorption layer and the second reaction gas, are discharged to clean the inside of the reaction chamber (reference numeral 27 in FIG. 2). It is then determined whether the second thin film has been formed to a desired thickness (reference numeral 29 in FIG. 2). The cycle of forming the second thin film (20) may be repeatedly performed until the second thin film having the desired thickness has been formed on the substrate.

The first thin film and the second thin film are thereby formed as stacked thin films adapted to act as a composite thin film. It is then determined whether the composite thin film has a desired thickness (reference numeral 39 in FIG. 2). The cycle of forming the first thin film (10) and the cycle of forming the second thin film (20) may be repeatedly performed until a composite thin film having the desired thickness has been formed on the substrate.

Based on practice of the present invention as described above, some of the literature in this field might seem to suggest a tendency that the uniformity of the deposited thin film would be degraded as the plasma-on-time condition is lengthened. On the contrary, however, as the plasma-on-time condition is lengthened (at least within certain limits), it has been surprisingly found that a thin film having a good leakage current characteristic may be obtained. Accordingly, the first thin film may be superior in uniformity to the second thin film. On the other hand, the second thin film may have a leakage current characteristic superior to that of the first thin film. As a result of forming a composite thin film comprising stacked layers of the first and second thin films, the composite thin film can be formed to demonstrate both a good leakage current characteristic and a good uniformity.

In addition, deposition speed and the specific properties of the composite thin film may be adjusted by repeatedly performing the cycle of forming the first thin film (10), and may also be adjusted by repeatedly performing the cycle of forming the second thin film (20) a desired number of times. In addition, the deposition speed and the specific properties of the composite thin film may be adjusted by repeatedly performing the two cycles of forming the first thin film (10) and the cycle of forming the second thin film (20).

In different invention embodiments, the thickness of the second thin film may be equal to or larger than that of the first thin film.

The second thin film may be formed of the same material as the first thin film, or alternatively, it may be formed of a material different from the first thin film.

Alternatively, still another method of forming a thin film according to still another embodiment of the present invention includes the step of loading a substrate into a reaction chamber of an atomic layer deposition apparatus (reference numeral 5 in FIG. 2).

A cycle of forming a first thin film (10) is repeatedly performed to form the first thin film having a desired thickness on a surface of the substrate. The cycle of forming the first thin film (10) may include a step of injecting a first source gas (reference numeral 11 in FIG. 2), a step of discharging the first source gas remaining within the reaction chamber to clean the inside of the reaction chamber (reference numeral 13 in FIG. 2), a step of injecting the first reaction gas into the reaction chamber at a first flow rate (reference numeral 15 in FIG. 2), and a step of cleaning the inside of the reaction chamber (reference numeral 17 in FIG. 2).

Describing this embodiment in greater detail, the first source gas containing a first atom is injected into the reaction chamber where the substrate is already loaded (reference numeral 11 in FIG. 2). The first atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the first atom is formed on an exposed surface of the substrate. After the chemical adsorption layer containing the first atom is formed, the first source gas remaining within the reaction chamber is discharged to clean the inside of the reaction chamber (reference numeral 13 in FIG. 2). Subsequently, the first reaction gas is injected into the reaction chamber at the first flow rate (reference numeral 15 in FIG. 2). The first flow rate may be a value selected in the range greater than 0 sccm and less than about 300 sccm. The first reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the first reaction gas react with each other to form the first thin film on the substrate surface. The first thin film may be an oxide layer, a nitride layer or an oxynitride layer of the first atom. Subsequently, any first reaction gas remaining within the reaction chamber, and any by-product generated due to the reaction between the chemical adsorption layer and the first reaction gas are discharged to clean the inside of the reaction chamber (reference numeral 17 in FIG. 2). It is then determined whether the first thin film has been formed to a desired thickness (reference numeral 19 in FIG. 2). The cycle of forming the first thin film (10) may be repeatedly performed until the first thin film having the desired thickness is formed on the substrate.

A cycle of forming a second thin film (20) is repeatedly performed on the substrate having the first thin film to form the second thin film having a desired thickness. The cycle of forming the second thin film (20) may include a step of injecting a second source gas (reference numeral 21 in FIG. 2), a step of discharging the second source gas remaining within the reaction chamber to clean the inside of the reaction chamber (reference numeral 23 in FIG. 2), a step of injecting a second reaction gas at a second flow rate which is higher than the first flow rate (reference numeral 25 in FIG. 2), and a step of cleaning the inside of the reaction chamber (reference numeral 27 in FIG. 2).

Describing this embodiment in greater detail, the second source gas containing a second atom is injected into the reaction chamber (reference numeral 21 in FIG. 2). The second atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the second atom is formed on the substrate surface having the first thin film. After the chemical adsorption layer containing the second atom is formed, the second source gas remaining within the reaction chamber is discharged to clean the inside of the reaction chamber (reference numeral 23 in FIG. 2). Subsequently, the second reaction gas is injected into the reaction chamber at the second flow rate (which is higher than the first flow rate) (reference numeral 25 in FIG. 2). The second flow rate may be a value selected in the range greater than the first flow rate and less than about 5000 sccm. The second reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the second reaction gas react with each other to form the second thin film on the substrate surface. The second thin film may be an oxide layer, a nitride layer or an oxynitride layer of the second atom. Subsequently, any second reaction gas remaining within the reaction chamber, and any by-product generated due to the reaction between the chemical adsorption layer and the second reaction gas, are discharged to clean the inside of the reaction chamber (reference numeral 27 in FIG. 2). It is then determined whether the second thin film has been formed to a desired thickness (reference numeral 29 in FIG. 2). The cycle of forming the second thin film (20) may be repeatedly performed until the second thin film having the desired thickness has been formed on the substrate.

The first thin film and the second thin film are thereby formed as stacked thin films adapted to act as a composite thin film. It is then determined whether the composite thin film has a desired thickness (reference numeral 39 in FIG. 2). The cycle of forming the first thin film (10) and the cycle of forming the second thin film (20) may be repeatedly performed until a composite thin film having the desired thickness has been formed on the substrate.

Based on practice of the present invention as described above, it has been found that a good uniformity of the deposited thin film may be obtained at a relatively low flow rate of first reaction gas compared to a relatively higher flow rate used when the second reaction gas is injected. Accordingly, the first thin film may be superior in uniformity relative to the second thin film. As a result of forming a composite thin film comprising stacked layers of the first and second thin films, therefore, a composite thin film may be formed that is overall excellent in uniformity.

In addition, deposition speed and specific properties of the composite thin film may be adjusted by repeatedly performing the cycle of forming the first thin film (10), and may also be adjusted by repeatedly performing the cycle of forming the second thin film (20) a desired number of times. In addition, the deposition speed and the specific properties of the composite thin film may be adjusted by repeatedly performing the two cycles of forming the first thin film (10) and the cycle of forming the second thin film (20).

In different invention embodiments, the thickness of the second thin film may be equal to or larger than that of the first thin film.

The second thin film may be formed of the same material as the first thin film, or, alternatively, it may be formed of a material different from the first thin film.

Alternatively, yet another method of forming a thin film according to yet another embodiment of the present invention includes the step of loading a substrate into a reaction chamber of an atomic layer deposition apparatus (reference numeral 5 in FIG. 2).

A cycle of forming a first thin film (10) is repeatedly performed to form the first thin film having a desired thickness on a surface of the substrate. The cycle of forming the first thin film (10) may include a step of injecting a first source gas (reference numeral 11 in FIG. 2), a step of discharging the first source gas remaining within the reaction chamber to clean the inside of the reaction chamber (reference numeral 13 in FIG. 2), a step of injecting a first reaction gas under the process condition of a first pressure (reference numeral 15 in FIG. 2), and a step of cleaning the inside of the reaction chamber (reference numeral 17 in FIG. 2).

Describing this embodiment in greater detail, the first source gas containing a first atom is injected into the reaction chamber where the substrate is already loaded (reference numeral 11 in FIG. 2). The first atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the first atom is formed on an exposed surface of the substrate. After the chemical adsorption layer containing the first atom is formed, the first source gas remaining within the reaction chamber is discharged to clean the inside of the reaction chamber (reference numeral 13 in FIG. 2). Subsequently, a first reaction gas is injected under the process condition of a first pressure (reference numeral 15 in FIG. 2). The first pressure may be a value selected in the range equal to or greater than about 3 Torr and less than about 30 Torr. The first reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the first reaction gas react with each other to form the first thin film on the substrate surface. The first thin film may be an oxide layer, a nitride layer or an oxynitride layer of the first atom. Subsequently, any first reaction gas remaining within the reaction chamber, and any by-product generated due to the reaction between the chemical adsorption layer and the first reaction gas, are discharged to clean the inside of the reaction chamber (reference numeral 17 in FIG. 2). It is then determined whether the first thin film has been formed to a desired thickness (reference numeral 19 in FIG. 2). The cycle of forming the first thin film (10) may be repeatedly performed until the first thin film having the desired thickness has been formed on the substrate.

A cycle of forming a second thin film (20) is repeatedly performed on the substrate having the first thin film to form the second thin film having a desired thickness. The cycle of forming the second thin film (20) may include a step of injecting a second source gas (reference numeral 21 in FIG. 2), a step of discharging the second source gas remaining within the reaction chamber to clean the inside of the reaction chamber (reference numeral 23 in FIG. 2), a step of injecting a second reaction gas into the reaction chamber under the process condition of a second pressure which is lower than the first pressure (reference numeral 25 in FIG. 2), and a step of cleaning the inside of the reaction chamber (reference numeral 27 in FIG. 2).

Describing this embodiment in greater detail, the second source gas containing a second atom is injected into the reaction chamber (reference numeral 21 in FIG. 2). The second atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the second atom is formed on the substrate surface having the first thin film. After the chemical adsorption layer containing the second atom is formed, the second source gas remaining within the reaction chamber is discharged to clean the inside of the reaction chamber (reference numeral 23 in FIG. 2). Subsequently, the second reaction gas is injected into the reaction chamber under the process condition of a second pressure (which is lower than the first pressure) (reference numeral 25 in FIG. 2). The second pressure may be a value selected in the range greater than 0 Torr and less than the first pressure. The second reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the second reaction gas react with each other to form the second thin film on the substrate surface. The second thin film may be an oxide layer, a nitride layer or an oxynitride layer of the second atom. Subsequently, any second reaction gas remaining within the reaction chamber, and any by-product generated due to the reaction between the chemical adsorption layer and the second reaction gas, are discharged to clean the inside of the reaction chamber (reference numeral 27 in FIG. 2). It is then determined whether the second thin film has been formed to a desired thickness (reference numeral 29 in FIG. 2). The cycle of forming the second thin film (20) may be repeatedly performed until the second thin film having the desired thickness has been formed on the substrate.

The first thin film and the second thin film are thereby formed as stacked thin films adapted to act as a composite thin film. It is then determined whether the composite thin film has a desired thickness (reference numeral 39 in FIG. 2). The cycle of forming the first thin film (10) and the cycle of forming the second thin film (20) may be repeatedly performed until a composite thin film having the desired thickness has been formed on the substrate.

Based on practice of the present invention as described above, it has been found that a good uniformity of the deposited thin film may be obtained at a relatively high pressure of first reaction gas compared to a relatively low pressure used when the second reaction gas is injected. Accordingly, the first thin film may be superior in uniformity relative to the second thin film. As a result of forming a composite thin film comprising stacked layers of the first and second thin films, therefore, a composite thin film may be formed that is overall excellent in uniformity.

In addition, deposition speed and specific properties of the composite thin film may be adjusted by repeatedly performing the cycle of forming the first thin film (10), and may also be adjusted by repeatedly performing the cycle of forming the second thin film (20) a desired number of times. In addition, the deposition speed and specific properties of the composite thin film may be adjusted by repeatedly performing the two cycles of forming the first thin film (10) and the cycle of forming the second thin film (20).

In different invention embodiments, the thickness of the second thin film may be equal to or larger than that of the first thin film.

The second thin film may be formed of the same material as the first thin film, or, alternatively, it may be formed of a material different from the first thin film.

Alternatively, still another method of forming a thin film according to yet another embodiment of the present invention includes the step of loading a substrate into a reaction chamber of an atomic layer deposition apparatus (reference numeral 5 in FIG. 2).

The cycle of forming the first thin film (10) is repeatedly performed to form the first thin film having a desired thickness on a surface of the substrate. The cycle of forming the first thin film (10) may include a step of injecting a first source gas (reference numeral 11 in FIG. 2), a step of discharging the first source gas remaining within the reaction chamber to clean the inside of the reaction chamber (reference numeral 13 in FIG. 2), a step of injecting a first reaction gas under the process condition of a first pressure (reference numeral 15 in FIG. 2), and a step of cleaning the inside of the reaction chamber (reference numeral 17 in FIG. 2).

Describing this embodiment in greater detail, the first source gas containing a first atom is injected into the reaction chamber where the substrate is already loaded (reference numeral 11 in FIG. 2). The first atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the first atom is formed on an exposed surface of the substrate. After the chemical adsorption layer containing the first atom is formed, the first source gas remaining within the reaction chamber is discharged to clean the inside of the reaction chamber (reference numeral 13 in FIG. 2). Subsequently, the first reaction gas is injected at the first flow rate under the process condition of a first pressure (reference numeral 15 in FIG. 2). The first pressure may be a value selected in the range equal to or greater than about 3 Torr and less than about 30 Torr. The first flow rate may be a value selected in the range greater than 0 sccm and less than about 300 sccm. The first reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the first reaction gas react with each other to form the first thin film on the substrate surface. The first thin film may be an oxide layer, a nitride layer or an oxynitride layer of the first atom. Subsequently, any first reaction gas remaining within the reaction chamber, and any by-product generated due to the reaction between the chemical adsorption layer and the first reaction gas, are discharged to clean the inside of the reaction chamber (reference numeral 17 in FIG. 2). It is then determined whether the first thin film has been formed to a desired thickness (reference numeral 19 in FIG. 2). The cycle of forming the first thin film (10) may be repeatedly performed until the first thin film having the desired thickness is formed on the substrate.

A cycle of forming a second thin film (20) is repeatedly performed on the substrate having the first thin film to form the second thin film having a desired thickness. The cycle of forming the second thin film (20) may include a step of injecting a second source gas (reference numeral 21 in FIG. 2), a step of discharging the second source gas remaining within the reaction chamber to clean the inside of the reaction chamber (reference numeral 23 in FIG. 2), a step of injecting a second reaction gas into the reaction chamber at a second flow rate higher than the first flow rate under the process condition of a second pressure which is lower than the first pressure (reference numeral 25 in FIG. 2), and a step of cleaning the inside of the reaction chamber (reference numeral 27 in FIG. 2).

Describing this embodiment in greater detail, the second source gas containing a second atom is injected into the reaction chamber (reference numeral 21 in FIG. 2). The second atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the second atom is formed on the substrate surface having the first thin film. After the chemical adsorption layer containing the second atom is formed, the second source gas remaining within the reaction chamber is discharged to clean the inside of the reaction chamber (reference numeral 23 in FIG. 2). Subsequently, the second reaction gas is injected into the reaction chamber at a second flow rate (which is higher than the first flow rate) and under the process condition of a second pressure (which is lower than the first pressure) (reference numeral 25 in FIG. 2). The second pressure may be a value selected in the range greater than 0 Torr and less than the first pressure. The second flow rate may be a value selected in the range greater than the first flow rate and less than about 5000 sccm. The second reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the second reaction gas react with each other to form the second thin film on the substrate surface. The second thin film may be an oxide layer, a nitride layer or an oxynitride layer of the second atom. Subsequently, any second reaction gas remaining within the reaction chamber, and any by-product generated due to the reaction between the chemical adsorption layer and the second reaction gas, are discharged to clean the inside of the reaction chamber (reference numeral 27 in FIG. 2). It is then determined whether the second thin film has been formed to a desired thickness (reference numeral 29 in FIG. 2). The cycle of forming the second thin film (20) may be repeatedly performed until the second thin film having the desired thickness has been formed on the substrate.

The first thin film and the second thin film are thereby formed as stacked thin films adapted to act as a composite thin film. It is then determined whether the composite thin film has a desired thickness (reference numeral 39 in FIG. 2). The cycle of forming the first thin film (10) and the cycle of forming the second thin film (20) may be repeatedly performed until a composite thin film having the desired thickness has been formed on the substrate.

Alternatively, still another method of forming a thin film according to yet another embodiment of the present invention includes the step of loading a substrate into a reaction chamber of an atomic layer deposition apparatus (reference numeral 5 in FIG. 2).

A cycle of forming a first thin film (10) is repeatedly performed to form the first thin film having a desired thickness on a surface of the substrate. The cycle of forming the first thin film (10) may include a step of injecting a first source gas (reference numeral 11 in FIG. 2), a step of discharging the first source gas remaining within the reaction chamber to clean the inside of the reaction chamber (reference numeral 13 in FIG. 2), a step of injecting a first reaction gas having first chemical reactivity into the reaction chamber (reference numeral 15 in FIG. 2), and a step of cleaning the inside of the reaction chamber (reference numeral 17 in FIG. 2).

Describing this embodiment in greater detail, the first source gas containing a first atom is injected into the reaction chamber where the substrate is already loaded (reference numeral 11 in FIG. 2). The first atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the first atom is formed on an exposed surface of the substrate. After the chemical adsorption layer containing the first atom is formed, the first source gas remaining within the reaction chamber is discharged to clean the inside of the reaction chamber (reference numeral 13 in FIG. 2). Subsequently, the first reaction gas having the first chemical reactivity is injected into the reaction chamber (reference numeral 15 in FIG. 2). The first reaction gas having the first chemical reactivity may be a gas having a relatively low chemical reactivity relative to the first atom. The first reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. Under suitable conditions, the chemical adsorption layer and the first reaction gas react with each other to form the first thin film on the substrate surface. The first thin film may be an oxide layer, a nitride layer or an oxynitride layer of the first atom. Subsequently, any first reaction gas remaining within the reaction chamber, and any by-product generated due to the reaction between the chemical adsorption layer and the first reaction gas, are discharged to clean the inside of the reaction chamber (reference numeral 17 in FIG. 2). It is then determined whether the first thin film is formed to a desired thickness (reference numeral 19 in FIG. 2). The cycle of forming the first thin film (10) may be repeatedly performed until the first thin film having the desired thickness is formed on the substrate.

A cycle of forming a second thin film (20) is repeatedly performed on the substrate having the first thin film to form the second thin film having a desired thickness. The cycle of forming the second thin film (20) may include a step of injecting a second source gas (reference numeral 21 in FIG. 2), a step of discharging the second source gas remaining within the reaction chamber to clean the inside of the reaction chamber (reference numeral 23 in FIG. 2), a step of injecting a second reaction gas having second chemical reactivity which is higher than the first chemical reactivity into the reaction chamber (reference numeral 25 in FIG. 2), and a step of cleaning the inside of the reaction chamber (reference numeral 27 in FIG. 2).

Describing this embodiment in greater detail, the second source gas containing a second atom is injected into the reaction chamber (reference numeral 21 in FIG. 2). The second atom may be at least one member selected from the group consisting of Al, Hf, Zr, La, Si, Ta, Ti, Sr, Ba, Pb, Cr, Mo, W, Y, and Mn. Under suitable conditions, a chemical adsorption layer containing the second atom is formed on the substrate surface having the first thin film. After the chemical adsorption layer containing the second atom is formed, the second source gas remaining within the reaction chamber is discharged to clean the inside of the reaction chamber (reference numeral 23 in FIG. 2). Subsequently, the second reaction gas having a second chemical reactivity (which is higher than the first chemical reactivity) is injected into the reaction chamber (reference numeral 25 in FIG. 2). The second reaction gas having the second chemical reactivity may be a gas having a relatively high chemical reactivity relative to the second atom. The second reaction gas may be at least one member selected from an oxygen (O)-containing gas, a nitrogen (N)-containing gas and a hydrogen(H₂) gas. The oxygen (O)-containing gas may be at least one member selected from the group consisting of O₂, O₃, H₂O, H₂O₂, NO₂, and N₂O. The nitrogen (N)-containing gas may be at least one member selected from the group consisting of N₂, NH₃, NO₂, and N₂O. For example, when the first and second atoms are each hafnium (Hf), the first reaction gas having the first chemical reactivity may be oxygen (O₂), and the second reaction gas having the second chemical reactivity may be ozone (O₃). As another example, the first reaction gas having the first chemical reactivity may be oxygen (O₂), and the second reaction gas having the second chemical reactivity may be oxygen plasma (O₂ plasma). As another example, the first reaction gas having the first chemical reactivity may be H₂O, and the second reaction gas having the second chemical reactivity may be oxygen plasma (O₂ plasma), ozone (O₃), ozone plasma (O₃ plasma). Alternatively, the second reaction gas having the second chemical reactivity may be a plasma-processed or photo-processed gas. Under suitable conditons, the chemical adsorption layer and the second reaction gas react with each other to form the second thin film on the substrate surface. The second thin film may be an oxide layer, a nitride layer or an oxynitride layer of the second atom. Subsequently, any second reaction gas remaining within the reaction chamber, and any by-product generated due to the reaction between the chemical adsorption layer and the second reaction gas, are discharged to clean the inside of the reaction chamber (reference numeral 27 in FIG. 2). It is then determined whether the second thin film has been formed to a desired thickness (reference numeral 29 in FIG. 2). The cycle of forming the second thin film (20) may be repeatedly performed until the second thin film having the desired thickness has been formed on the substrate.

The first thin film and the second thin film are thereby formed as stacked thin films adapted to act as a composite thin film. It is then determined whether the composite thin film has a desired thickness (reference numeral 39 in FIG. 2). The cycle of forming the first thin film (10) and the cycle of forming the second thin film (20) may be repeatedly performed until a composite thin film having the desired thickness has been formed on the substrate.

Based on practice of the present invention as described above, it has been found that a good uniformity of the deposited thin film may be obtained using a first reaction gas having a relatively low chemical reactivity compared to a second reaction gas having a relatively higher chemical reactivity. Accordingly, the first thin film may be superior in uniformity relative to the second thin film. As a result of forming a composite thin film comprising stacked layers of the first and second thin films, therefore, a composite thin film may be formed that is overall excellent in uniformity.

In addition, deposition speed and specific properties of the composite thin film may be adjusted by repeatedly performing the cycle of forming the first thin film (10), and may also be adjusted by repeatedly performing the cycle of forming the second thin film (20) a desired number of times. In addition, the deposition speed and the specific properties of the composite thin film may be adjusted by repeatedly performing the two cycles of forming the first thin film (10) and the cycle of forming the second thin film (20).

In different invention embodiments, the thickness of the second thin film may be equal to or larger than that of the first thin film.

The second thin film may be formed of the same material as the first thin film, or, alternatively, it may be formed of a material different from the first thin film.

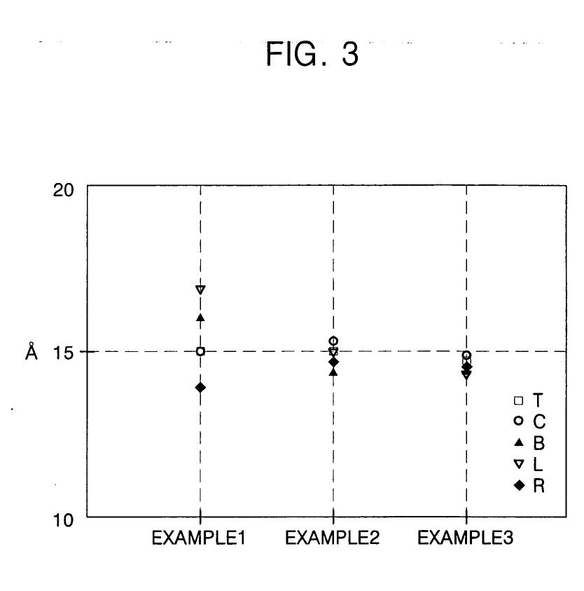

FIG. 3 is a scatter diagram illustrating uniformity of different thin films according to examples of the present invention.

Referring to FIG. 3, a silicon wafer was employed as the substrate in the examples of the present invention, and both the first and second source gases were tetrakis(ethylmethylamino)hafnium (TEMAH). TEMAH is a material denoted by the chemical formula Hf[N(CH₃)C₂H₅]₄. The vertical axis scale of FIG. 3 represents the thicknesses of the different thin films in Angstrom (A) units. Legends associated with the denoted points in FIG. 3 indicate positions of measuring the thickness of the thin film on the silicon wafer, that is, Top (T), Center (C), Bottom (B), Left (L), and Right (R).

According to example 1 representing a prior art thin film preparation technique, TEMAH was employed as the source gas, and oxygen (O₂) gas was employed as a reaction gas while a plasma of 250 W was applied and the atomic layer deposition process was carried out for 80 cycles. As a result, the scattered thickness (i.e., the variation in thin film thickness measured at different points) of the deposited hafnium oxide layer was about 2.5 Å.

In example 2, representing an embodiment of the present invention, 100 W was applied as the first plasma power and the oxygen (O₂) gas was employed as the first reaction gas to carry out an atomic layer deposition process for 10 cycles. Thereafter, 250 W was applied as the second plasma power and oxygen (O₂) gas was also employed as the second reaction gas to carry out an atomic layer deposition process for 70 cycles. As a result, the scattered thickness of the deposited hafnium oxide layer was only about 1 Å.

In example 3, representing another embodiment of the present invention, 0 W was applied as the first plasma power and the oxygen (O₂) gas was employed as the first reaction gas to carry out an atomic layer deposition process for 10 cycles. Thereafter, 250 W was applied as the second plasma power and oxygen (O₂) gas was also employed as the second reaction gas to carry out an atomic layer deposition process for 70 cycles. The applied plasma power of 0 W is substantially equivalent to the case of not using the plasma. As a result, the scattered thickness of the deposited hafnium oxide layer was about but not more than 1 Å.

In conclusion, the foregoing examples demonstrate that the uniformity of the thin films deposited in accordance with embodiments of the present invention is significantly improved compared to thin films prepared according to the prior art methods.

According to general principles of the present invention as discussed above, a first process condition capable of forming a thin film with good uniformity may be used to form a first thin film on a substrate, and thereafter a second process condition capable of obtaining improved deposition speed and/or desirable chemical and/or electrical characteristics may be used to form a second thin film on the substrate having the first thin film thereon. Also in accordance with this invention, repetition times of forming the first thin film and/or the second thin film may be controlled to adjust the deposition speed and specific properties of the resulting composite thin film. As a result, in addition to the enhancement of productivity, thin films having good uniformity may be formed with the methods of this invention.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a thin film by atomic layer deposition comprising the sequential steps of:
loading a substrate into a reaction chamber;
injecting a first source gas containing a first atom into the reaction chamber to form a chemical adsorption layer containing the first atom on a surface of the substrate;
injecting a first reaction gas into the reaction chamber while applying a first plasma power to the reaction chamber such that the first reaction gas reacts with the chemical adsorption layer containing the first atom to form a first thin film on the substrate;
injecting a second source gas containing a second atom into the reaction chamber to form a chemical adsorption layer containing the second atom on the substrate having the first thin film; and
injecting a second reaction gas into the reaction chamber while applying a second plasma power, which is higher than the first plasma power, to the reaction chamber such that the second reaction gas reacts with the chemical adsorption layer containing the second atom to form a second thin film on the substrate.

2. The method as claimed in claim 1, wherein the first plasma power is a value selected in a range equal to or greater than 0 W and less than about 500 W, and the second plasma power is a value selected in a range greater than the first-plasma power and less than about 2000 W.

3. The method as claimed in claim 1, wherein the first and second atom is at least one member selected from the group consisting of aluminum (Al), hafnium (Hf), zirconium (Zr), lanthanum (La), silicon (Si), tantalum (Ta), titanium (Ti), strontium (Sr), barium (Ba), lead (Pb), chromium (Cr), molybdenum (Mo), tungsten (W), yttrium (Y), and manganese (Mn).

4. The method as claimed in claim 1, wherein the first and second reaction gas contains at least one member selected from an oxygen (O)-containing gas, a nitrogen (N)-containing gas and a hydrogen(H₂) gas, further wherein the oxygen (O)-containing gas is at least one member selected from the group consisting of O₂, O₃, H₂O, H₂O₂, NO₂, and N₂O, and the nitrogen (N)-containing gas is at least one member selected from the group consisting of N₂, NH₃, NO₂, and N₂O.

5. The method as claimed in claim 1, wherein chemical and/or electrical properties and deposition speed of the thin film are adjusted by repeatedly performing the steps for forming the first thin film two or more times.

6. The method as claimed in claim 1, wherein chemical and/or electrical properties and deposition speed of the thin film are adjusted by repeatedly performing the steps for forming the second thin film two or more times.

7. The method as claimed in claim 1, wherein the second thin film has a thickness equal to or greater than a thickness of the first thin film.

8. The method as claimed in claim 1, wherein the second thin film is formed of the same material as the first thin film.

9. The method as claimed in claim 1, wherein the second thin film is formed of a material different from that of the first thin film.

10. A method of forming a thin film by atomic layer deposition comprising the sequential steps of:
loading a substrate into a reaction chamber;
injecting a first source gas containing a first atom into the reaction chamber to form a chemical adsorption layer containing the first atom on a surface of the substrate;
injecting a first reaction gas into the reaction chamber under a process condition of a first plasma-on-time condition such that the first reaction gas reacts with the chemical adsorption layer containing the first atom to form a first thin film on the substrate;
injecting a second source gas containing a second atom into the reaction chamber to form a chemical adsorption layer containing the second atom on the substrate having the first thin film; and
injecting a second reaction gas into the reaction chamber under a process condition of a second plasma-on-time condition, which is longer than the first plasma-on-time condition, such that the second reaction gas reacts with the chemical adsorption layer containing the second atom to form a second thin film on the substrate.

11. The method as claimed in claim 10, wherein the first plasma-on-time condition is a value selected in a range equal to or greater than 0 seconds and less than about 1 second, and the second plasma-on-time condition is a value selected in a range longer than the first plasma-on-time condition and less than about 30 seconds.

12. The method as claimed in claim 10, wherein the first and second atom is at least one member selected from the group consisting of aluminum (Al), hafnium (Hf), zirconium (Zr), lanthanum (La), silicon (Si), tantalum (Ta), titanium (Ti), strontium (Sr), barium (Ba), lead (Pb), chromium (Cr), molybdenum (Mo), tungsten (W), yttrium (Y), and manganese (Mn).

13. The method as claimed in claim 10, wherein the first and second reaction gas contains at least one member selected from an oxygen (O)-containing gas, a nitrogen (N)-containing gas and a hydrogen(H₂) gas, further wherein the oxygen (O)-containing gas is at least one member selected from the group consisting of O₂, O₃, H₂O, H₂O₂, NO₂, and N₂O, and the nitrogen (N)-containing gas is at least one member selected from the group consisting of N₂, NH₃, NO₂, and N₂O.

14. The method as claimed in claim 10, wherein chemical and/or electrical properties and deposition speed of the thin film are adjusted by repeatedly performing the steps for forming the first thin film two or more times.

15. The method as claimed in claim 10, wherein chemical and/or electrical properties and deposition speed of the thin film are adjusted by repeatedly performing the steps for forming the second thin film two or more times.

16. The method as claimed in claim 10, wherein the second thin film has a thickness equal to or greater than a thickness of the first thin film.

17. A method of forming a thin film by atomic layer deposition comprising the sequential steps of:
loading a substrate into a reaction chamber;
injecting a first source gas containing a first atom into the reaction chamber to form a chemical adsorption layer containing the first atom on the surface of the substrate;
injecting a first reaction gas into the reaction chamber at a first flow rate such that the first reaction gas reacts with the chemical adsorption layer containing the first atom to form a first thin film on the substrate;
injecting a second source gas containing a second atom into the reaction chamber to form a chemical adsorption layer containing the second atom on the substrate having the first thin film; and
injecting a second reaction gas into the reaction chamber at a second flow rate, which is higher than the first flow rate, such that the second reaction gas reacts with the chemical adsorption layer containing the second atom to form a second thin film on the substrate.

18. The method as claimed in claim 17, wherein the first flow rate is a value selected in a range greater than 0 sccm (standard cubic centimeter per minute) and less than about 300 sccm, and the second flow rate is a value selected in a range greater than the first flow rate and less than about 5000 sccm.

19. The method as claimed in claim 17, wherein the first and second atom is at least one member selected from the group consisting of aluminum (Al), hafnium (Hf), zirconium (Zr), lanthanum (La), silicon (Si), tantalum (Ta), titanium (Ti), strontium (Sr), barium (Ba), lead (Pb), chromium (Cr), molybdenum (Mo), tungsten (W), yttrium (Y), and manganese (Mn).

20. The method as claimed in claim 17, wherein the first and second reaction gas contains at least one member selected from an oxygen (O)-containing gas, a nitrogen (N)-containing gas and a hydrogen(H₂) gas, further wherein the oxygen (O)-containing gas is at least one member selected from the group consisting of O₂, O₃, H₂O, H₂O₂, NO₂, and N₂O, and the nitrogen (N)-containing gas is at least one member selected from the group consisting of N₂, NH₃, NO₂, and N₂O.

21. The method as claimed in claim 17, wherein chemical and/or electrical properties and deposition speed of the thin film are adjusted by repeatedly performing the steps for forming the first thin film two or more times.

22. The method as claimed in claim 17, wherein chemical and/or electrical properties and deposition speed of the thin film are adjusted by repeatedly performing the steps for forming the second thin film two or more times.

23. The method as claimed in claim 17, wherein the second thin film has a thickness equal to or greater than a thickness of the first thin film.

24. A method of forming a thin film by atomic layer deposition comprising the sequential steps of:
loading a substrate into a reaction chamber;
injecting a first source gas containing a first atom into the reaction chamber to form a chemical adsorption layer containing the first atom on a surface of the substrate;
injecting a first reaction gas into the reaction chamber under a process condition of a first pressure such that the first reaction gas reacts with the chemical adsorption layer containing the first atom to form a first thin film on the substrate;
injecting a second source gas containing a second atom into the reaction chamber to form a chemical adsorption layer containing the second atom on the substrate having the first thin film; and
injecting a second reaction gas into the reaction chamber under a process condition of a second pressure, which is lower than the first pressure, such that the second reaction gas reacts with the chemical adsorption layer containing the second atom to form a second thin film on the substrate.

25. The method as claimed in claim 24, wherein the first pressure is a value selected in a range equal to or greater than about 3 Torr and less than about 30 Torr, and the second pressure is a value selected in a range greater than 0 Torr and less than the first pressure.

26. The method as claimed in claim 24, wherein the first and second atom is at least one member selected from the group consisting of aluminum (Al), hafnium (Hf), zirconium (Zr), lanthanum (La), silicon (Si), tantalum (Ta), titanium (Ti), strontium (Sr), barium (Ba), lead (Pb), chromium (Cr), molybdenum (Mo), tungsten (W), yttrium (Y), and manganese (Mn).

27. The method as claimed in claim 24, wherein the first and second reaction gas contains at least one member selected from an oxygen (O)-containing gas, a nitrogen (N)-containing gas and a hydrogen(H₂) gas, further wherein the oxygen (O)-containing gas is at least one member selected from the group consisting of O₂, O₃, H₂O, H₂O₂, NO₂, and N₂O, and the nitrogen (N)-containing gas is at least one member selected from the group consisting of N₂, NH₃, NO₂, and N₂O.

28. The method as claimed in claim 24, wherein chemical and/or electrical properties and deposition speed of the thin film are adjusted by repeatedly performing the steps for forming the first thin film two or more times.

29. The method as claimed in claim 24, wherein chemical and/or electrical properties and deposition speed of the thin film are adjusted by repeatedly performing the steps for forming the second thin film two or more times.

30. The method as claimed in claim 24, wherein the second thin film has a thickness equal to or greater than a thickness of the first thin film.

31. A method of forming a thin film by atomic layer deposition comprising the sequential steps of:
loading a substrate into a reaction chamber;
injecting a first source gas containing a first atom into the reaction chamber to form a chemical adsorption layer containing the first atom on a surface of the substrate;
injecting a first reaction gas into the reaction chamber at a first flow rate under a process condition of a first pressure such that the first reaction gas reacts with the chemical adsorption layer containing the first atom to form a first thin film on the substrate;
injecting a second source gas containing a second atom into the reaction chamber to form a chemical adsorption layer containing the second atom on the substrate having the first thin film; and
injecting a second reaction gas into the reaction chamber at a second flow rate which is higher than the first flow rate, and under a process condition of a second pressure which is lower than the first pressure, such that the second reaction gas reacts with the chemical adsorption layer containing the second atom to form a second thin film on the substrate.

32. The method as claimed in claim 31, wherein the first flow rate is a value selected in a range greater than 0 sccm (standard cubic centimeter per minute) and less than about 300 sccm, the second flow rate is a value selected in a range greater than the first flow rate and less than about 5000 sccm, the first pressure is a value selected in a range equal to or greater than about 3 Torr and less than about 30 Torr, and the second pressure is a value selected in a range greater than 0 Torr and less than the first pressure.

33. A method of forming a thin film by atomic layer deposition comprising the sequential steps of:
loading a substrate into a reaction chamber;
injecting a first source gas containing a first atom into the reaction chamber to form a chemical adsorption layer containing the first atom on a surface of the substrate;
injecting a first reaction gas having a first chemical reactivity into the reaction chamber such that the first reaction gas reacts with the chemical adsorption layer containing the first atom to form a first thin film oh the substrate;
injecting a second source gas containing a second atom into the reaction chamber to form a chemical adsorption layer containing the second atom on the substrate having the first thin film; and
injecting a second reaction gas having a second chemical reactivity which is higher than the first chemical reactivity, into the reaction chamber such that the second reaction gas reacts with the chemical adsorption layer containing the second atom to form a second thin film on the substrate.

34. The method as claimed in claim 33, wherein the first reaction gas having the first chemical reactivity is a gas having a relatively low chemical reactivity relative to the first atom, and the second reaction gas having the second chemical reactivity is a gas having a relatively high chemical reactivity relative to the second atom.

35. The method as claimed in claim 33, wherein the first and second reaction gas contains at least one member selected from an oxygen (O)-containing gas, a nitrogen (N)-containing gas and a hydrogen(H₂) gas, further wherein the oxygen (O)-containing gas is at least one member selected from the group consisting of O₂, O₃, H₂O, H₂O₂, NO₂, and N₂O, and the nitrogen (N)-containing gas is at least one member selected from the group consisting of N₂, NH₃, NO₂, and N₂O.

36. The method as claimed in claim 33, wherein the second reaction gas having the second chemical reactivity is a plasma-processed gas or a photo-processed gas.

37. The method as claimed in claim 33, wherein the first and second atom is at least one member selected from the group consisting of aluminum (Al), hafnium (Hf), zirconium (Zr), lanthanum (La), silicon (Si), tantalum (Ta), titanium (Ti), strontium (Sr), barium (Ba), lead (Pb), chromium (Cr), molybdenum (Mo), tungsten (W), yttrium (Y), and manganese (Mn).

38. The method as claimed in claim 33, wherein chemical and/or electrical properties and deposition speed of the thin film are adjusted by repeatedly performing the steps for forming the first thin film two or more times.

39. The method as claimed in claim 33, wherein chemical and/or electrical properties and deposition speed of the thin film are adjusted by repeatedly performing the steps for forming the second thin film two or more times.

40. The method as claimed in claim 33, wherein the second thin film has a thickness equal to or greater than a thickness of the first thin film.

41. The method as claimed in claim 33, wherein the first reaction gas is a H₂O, and the second reaction gas is at least one member selected from the group consisting of O₂-plasma, O₃, and O₃-plasma.
